(19) United States
(12) Patent Application Publication
(10) Pub. No.: US 2022/0082638 A1
(43) Pub. Date: Mar. 17, 2022

(54) CONNECTION TESTER

(71) Applicants: Kabushiki Kaisha Toshiba, Tokyo (JP); Toshiba Electronic Devices & Storage Corporation, Tokyo (JP)

(72) Inventor: Nozomu OKAZAKI, Kawasaki Kanagawa (JP)

(21) Appl. No.: 17/468,519

(22) Filed: Sep. 7, 2021

(30) Foreign Application Priority Data
Sep. 17, 2020 (JP) 2020-156401

(51) Int. Cl. G01R 31/66; G06F 13/40

(52) U.S. Cl. CPC G01R 31/66; G06F 13/4081; G06F 13/4022

(57) ABSTRACT

According to one embodiment, a connection tester includes first input terminals connected to first output terminals of a signal supply unit which supplies a signal, second output terminals connected to second input terminals of a device connectable to the first output terminals, a plurality of wiring members connecting the first input terminals and the second output terminals to each other, a plurality of switches respectively provided in the plurality of wiring members, and a control unit which controls on/off timing of each of the plurality of switches.

### CROSS-REFERENCE TO RELATED APPLICATIONS

This application is based upon and claims the benefit of priority from Japanese Patent Application No. 2020-156401, filed Sep. 17, 2020, the entire contents of which are incorporated herein by reference.

### FIELD

Embodiments described herein relate generally to a connection tester.

### BACKGROUND

In an electronic device, an interface (I/F) compatible with Serial Attached SCSI (SAS) and Serial Advanced Technology Attachment (SATA) and the like is used. In recent years, an electronic device, for example, a storage device such as a hard disk drive (HDD) or the like is compatible with hot swap. Further, in order to execute hot swap, it is necessary that each of the storage device and electronic device to which the storage device is connected, for example, a device such as a host or the like and components such as a device-cable and device-connector be compatible with hot swap. However, there is also a case where a device and components incompatible with hot swap are used without intention. In this case, damage is accumulated in the electronic circuit of the device due an overvoltage caused by a rush current or overshoot occurring at the time of hot plug, and there is a possibility of the elements suffering damage. Even in such a case, in order that the device may operate normally without any failure or the like, it is necessary that tests of connecting terminals of a connector be carried out in various patterns. It is difficult to verify hot swap by manually connecting a connector because of occurrence of variations in the speed of connecting the connector or variations in the inclination or the like of the connector at the time of connection.

### BRIEF DESCRIPTION OF THE DRAWINGS

FIG. 1 is a block diagram showing an example of a connection tester according to a first embodiment.

FIG. 2 is a schematic view showing an example of timing of manually connecting between output terminals of a SATA power source of an electronic device compatible with hot swap and input terminals of a SATA power source of an electronic device compatible with hot swap.

FIG. 3 is a schematic view showing an example of timing of manually connecting between output terminals of a SATA power source of an electronic device incompatible with hot swap and input terminals of a SATA power source of an electronic device incompatible with hot swap.

FIG. 4 is an outline view showing a configuration example of the connection tester according to the first embodiment.

FIG. 5 is an outline view showing an example of a method of measuring currents and voltages of the connection tester and electronic device.

FIG. 6 is an outline view showing an example of a method of confirming the state of the electronic device in a case where an electronic device is electrically connected thereto by artificial hot plug by the connection tester.

FIG. 7 is an outline view showing an example of a method of confirming the state of the electronic device in a case where an electronic device is electrically connected thereto by artificial hot plug by the connection tester.

FIG. 8 is an outline view showing a configuration example of a connection tester according to a modified example 1.

FIG. 9 is an outline view showing a configuration example of a connection tester according to a modified example 2.

FIG. 10 is an outline view showing a configuration example of a connection tester according to a modified example 3.

FIG. 11 is an outline view showing a configuration example of a connection tester according to a modified example 4.

FIG. 12 is an outline view showing a configuration example of a connection tester according to a modified example 5.

FIG. 13 is an outline view showing a configuration example of a connection tester according to a modified example 6.

FIG. 14 is a block diagram showing an example of a connection tester according to a second embodiment.

FIG. 15 is an outline view showing a configuration example of the connection tester according to the second embodiment.

### DETAILED DESCRIPTION

In general, according to one embodiment, a connection tester comprises: first input terminals connected to first output terminals of a signal supply unit which supplies a signal; second output terminals connected to second input terminals of a device connectable to the first output terminals; a plurality of wiring members connecting the first input terminals and the second output terminals to each other; a plurality of switches respectively provided in the plurality of wiring members; and a control unit which controls on/off timing of each of the plurality of switches.

Embodiments will be described hereinafter with reference to the accompanying drawings. It should be noted that the drawings are only examples and are not intended to limit the scope of the invention.

### First Embodiment

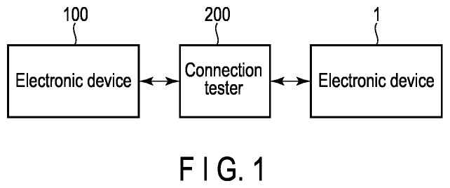

FIG. 1 is a block diagram showing an example of a connection tester 200 according to a first embodiment. The connection tester 200 is electrically connected to an electronic device (electronic apparatus or device) 100 and electronic device (electronic apparatus or device) 1. In the example shown in FIG. 1, in the connection tester 200, the electronic device 100 is connected to one end part thereof, and electronic device 1 is connected to the other end part thereof on the opposite side of the one end part. The connection tester 200 controls the timing of electrically connecting the electronic device (hereinafter referred to as connection timing in some cases), and executes a test of the connection state of the electronic device. The connection tester 200 controls timing of electrical connection between the electronic device 100 and electronic device 1. The connection tester 200 controls timing of electrical connection between the connector of the electronic device 100 and connector of the electronic device 1 in such a manner that the electrical connection timing corresponds to the timing of manual connection between the connector (terminals) of the electronic device 100 and connector (terminals) of the electronic device 1. In other words, the connection tester 200 reproduces the timing of manual connection between the connector (terminals) of the electronic device 100 and connector (terminals) of the electronic device 1. The connection tester 200 reproduces the timing of manual connection between the connector (terminals) of the hot-swappable electronic device 100 in which plugging (attachment)/unplugging (detachment) of the connector (terminals) or the like is enabled in a state where the power is kept on and the operation status is maintained, and connector (terminals) of the hot-swappable electronic device 1. The connection tester 200 may also be capable of reproducing the timing of manual connection between the non-hot-swappable electronic device 100 and non-hot-swappable electronic device 1.

The electronic device 1 is, for example, a storage device such as a hard disk drive (HDD), solid state drive (SSD), and the like. It should be noted that the electronic device 1 may also be an electronic device other than the storage device. The electronic device 1 is compatible with, for example, hot swap. When the electronic device 1 is compatible with hot swap, each of the components of the electronic device 1 is also compatible with hot swap. The electronic device 1 includes an interface (I/F) conforming to, for example, Serial Attached SCSI (SAS) (registered trade mark), Serial Advanced Technology Attachment (SATA) (registered trade mark), and the like. For example, the electronic device 1 includes a SATA power source connector. It should be noted that the electronic device 1 may also be incompatible with hot swap. When the electronic device 1 is incompatible with hot swap, each of the components of the electronic device 1 is also incompatible with hot swap. Further, the electronic device 1 may also be formed physically hot-swappable irrespective of whether the device 1 is compatible or incompatible with hot swap.

The electronic device 100 is, for example, a host system (hereinafter simply referred to as a host in some cases), computer such as a personal computer, supercomputer or the like, tablet device, smartphone, server, and the like. The electronic device 100 is compatible with, for example, hot swap. When the electronic device 100 is compatible with hot swap, each of the components of the electronic device 100 is also compatible with hot swap. The electronic device 100 includes an interface (I/F) conforming to, for example, SAS, SATA, and the like. For example, the electronic device 100 includes a SATA power source connector. It should be noted that the electronic device 100 may also be incompatible with hot swap. When the electronic device 100 is incompatible with hot swap, each of the components of the electronic device 100 is also incompatible with hot swap. Further, the electronic device 100 may also be formed physically hot-swappable irrespective of whether the device 100 is compatible or incompatible with hot swap.

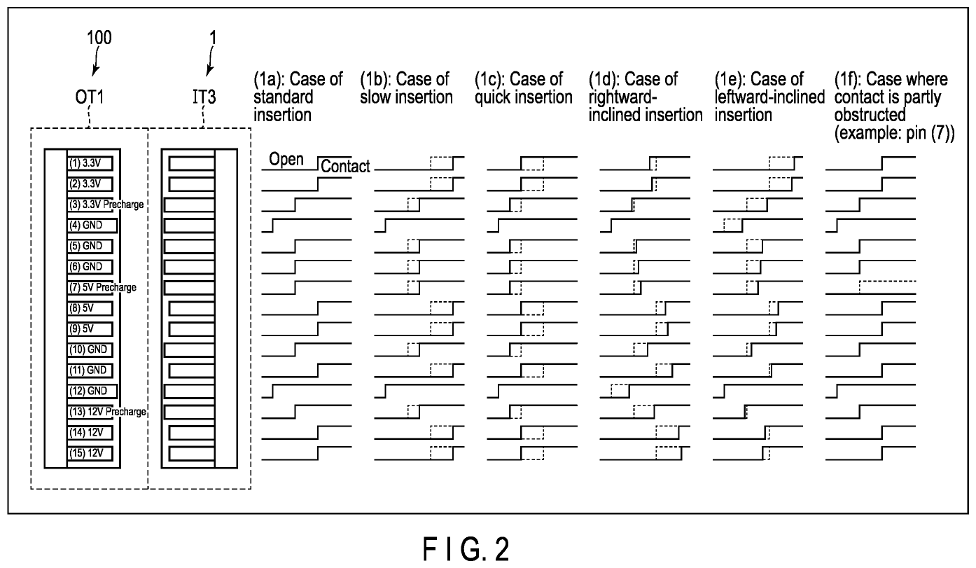

FIG. 2 is a schematic view showing an example of timing of manually connecting between output terminals OT1 of a SATA power source of the electronic device 100 compatible with hot swap and input terminals IT3 of a SATA power source of the electronic device 1 compatible with hot swap. In FIG. 2, the output terminals OT1 of the SATA power source of the electronic device 100 compatible with hot swap and input terminals IT3 of the SATA power source of the electronic device 1 compatible with hot swap are shown. In FIG. 2, the output terminals OT1 include fifteen pins. The output terminals OT1 include pins (1), (2), and (3) compatible with a voltage of 3.3 V, pins (4), (5), and (6) compatible with ground (GND), pins (7), (8), and (9) compatible with a voltage of 5 V, pins (10), (11), and (12) compatible with ground (GND), and pins (13), (14), and (15) compatible with a voltage of 12 V. In FIG. 2, each of the pins (3), (7), and (13) is connected to a pre-charge resistor. Lengths of the pins (4) and (12) are longer than lengths of the other pins. In FIG. 2, the input terminals IT3 includes fifteen pins respectively corresponding to the fifteen pins of the output terminals OT1. Lengths of the plurality of pins of the input terminals IT3 respectively opposed to the pins (3), (4), (5), (6), (7), (10), (12), and (13) of the output terminals OT1 are longer than lengths of the other pins.

In FIG. 2, a pattern (1a) indicating the timing of contact (or connection) between each of the pins of the output terminals OT1 and each of the pins of the input terminals IT3 of a case where the output terminals OT1 compatible with hot swap and input terminals IT3 compatible with hot swap are engaged with each other in a standard manner is shown. In the pattern (1a) indicating the timing of contact between each of the pins of the output terminals OT1 and each of the pins of the input terminals IT3 of a case where the output terminals OT1 compatible with hot swap and input terminals IT3 compatible with hot swap are engaged with each other in a standard manner, each of the pins of the output terminals OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern.

In FIG. 2, a pattern (1b) indicating the timing of contact (or connection) between each of the pins of the output terminals OT1 and each of the pins of the input terminals IT3 of a case where the output terminals OT1 compatible with hot swap and input terminals IT3 compatible with hot swap are engaged with each other in a slow manner is shown. In the pattern (1b) indicating the timing of contact between each of the pins of the output terminals OT1 and each of the pins of the input terminals IT3 of a case where the output terminals OT1 compatible with hot swap and input terminals IT3 compatible with hot swap are engaged with each other in a slow manner, each of the pins of the output terminals

OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern. In the pattern (1b) indicating the timing of contact between each of the pins of the output terminals OT1 and each of the pins of the input terminals IT3 of a case where the output terminals OT1 compatible with hot swap and input terminals IT3 compatible with hot swap are engaged with each other in a slow manner, the pattern of the dotted line indicates the pattern (1a) indicating the timing of contact between each of the pins of the output terminals OT1 and each of the pins of the input terminals IT3 of a case where the output terminals OT1 compatible with hot swap and input terminals IT3 compatible with hot swap are engaged with each other in a standard manner.

In FIG. 2, a pattern (1c) indicating the timing of contact (or connection) between each of the pins of the output terminals OT1 and each of the pins of the input terminals IT3 of a case where the output terminals OT1 compatible with hot swap and input terminals IT3 compatible with hot swap are engaged with each other in a quick manner is shown. In the pattern (1c) indicating the timing of contact between each of the pins of the output terminals OT1 and each of the pins of the input terminals IT3 of a case where the output terminals OT1 compatible with hot swap and input terminals IT3 compatible with hot swap are engaged with each other in a quick manner, each of the pins of the output terminals OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern. In the pattern (1c) indicating the timing of contact between each of the pins of the output terminals OT1 and each of the pins of the input terminals IT3 of a case where the output terminals OT1 compatible with hot swap and input terminals IT3 compatible with hot swap are engaged with each other in a quick manner, the pattern of the dotted line indicates the pattern (1a) indicating the timing of contact between each of the pins of the output terminals OT1 and each of the pins of the input terminals IT3 of a case where the output terminals OT1 compatible with hot swap and input terminals IT3 compatible with hot swap are engaged with each other in a standard manner.

In FIG. 2, a pattern (1d) indicating the timing of contact (or connection) between each of the pins of the output terminals OT1 and each of the pins of the input terminals IT3 of a case where the output terminals OT1 compatible with hot swap and input terminals IT3 compatible with hot swap are engaged with each other in a rightward-inclined manner is shown. In the pattern (1d) indicating the timing of contact between each of the pins of the output terminals OT1 and each of the pins of the input terminals IT3 of a case where the output terminals OT1 compatible with hot swap and input terminals IT3 compatible with hot swap are engaged with each other in a rightward-inclined manner, each of the pins of the output terminals OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern. In the pattern (1d) indicating the timing of contact between each of the pins of the output terminals OT1 and each of the pins of the input terminals IT3 of a case where the output terminals OT1 compatible with hot swap and input terminals IT3 compatible with hot swap are engaged with each other in a rightward-inclined manner, the pattern of the dotted line indicates the pattern (1a) indicating the timing of contact between each of the pins of the output terminals OT1 and each of the pins of the input terminals IT3 of a case where the output terminals OT1 compatible with hot swap and input terminals IT3 compatible with hot swap are engaged with each other in a standard manner.

In FIG. 2, a pattern (1e) indicating the timing of contact (or connection) between each of the pins of the output terminals OT1 and each of the pins of the input terminals IT3 of a case where the output terminals OT1 compatible with hot swap and input terminals IT3 compatible with hot swap are engaged with each other in a leftward-inclined manner is shown. In the pattern (1e) indicating the timing of contact between each of the pins of the output terminals OT1 and each of the pins of the input terminals IT3 of a case where the output terminals OT1 compatible with hot swap and input terminals IT3 compatible with hot swap are engaged with each other in a leftward-inclined manner, each of the pins of the output terminals OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern. In the pattern (1e) indicating the timing of contact between each of the pins of the output terminals OT1 and each of the pins of the input terminals IT3 of a case where the output terminals OT1 compatible with hot swap and input terminals IT3 compatible with hot swap are engaged with each other in a leftward-inclined manner, the pattern of the dotted line indicates the pattern (1a) indicating the timing of contact between each of the pins of the output terminals OT1 and each of the pins of the input terminals IT3 of a case where the output terminals OT1 compatible with hot swap and input terminals IT3 compatible with hot swap are engaged with each other in a standard manner.

In FIG. 2, a pattern (1f) indicating the timing of contact (or connection) between each of the pins of the output terminals OT1 and each of the pins of the input terminals IT3 of a case where the output terminals OT1 compatible with hot swap and input terminals IT3 compatible with hot swap are engaged with each other in a state where part of the contact (connection) is obstructed by contamination or the like with a foreign substance is shown. In the pattern (1f) indicating the timing of contact between each of the pins of the output terminals OT1 and each of the pins of the input terminals IT3 of a case where the output terminals OT1 compatible with hot swap and input terminals IT3 compatible with hot swap are engaged with each other in a state where part of the contact (connection) is obstructed, each of the pins of the output terminals OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern. In the pattern (1f) indicating the timing of contact between each of the pins of the output terminals OT1 and each of the pins of the input terminals IT3 of a case where the output terminals OT1 compatible with hot swap and input terminals IT3 compatible with hot swap are engaged with each other in a state where part of the contact (connection) is obstructed, the pattern of the dotted line indicates the pattern (1a) indicating the timing of contact between each of the pins of the output terminals OT1 and each of the pins of the input terminals IT3 of a case where the output terminals OT1 compatible with hot swap and input terminals IT3 compatible with hot swap are engaged with each other in a standard manner.

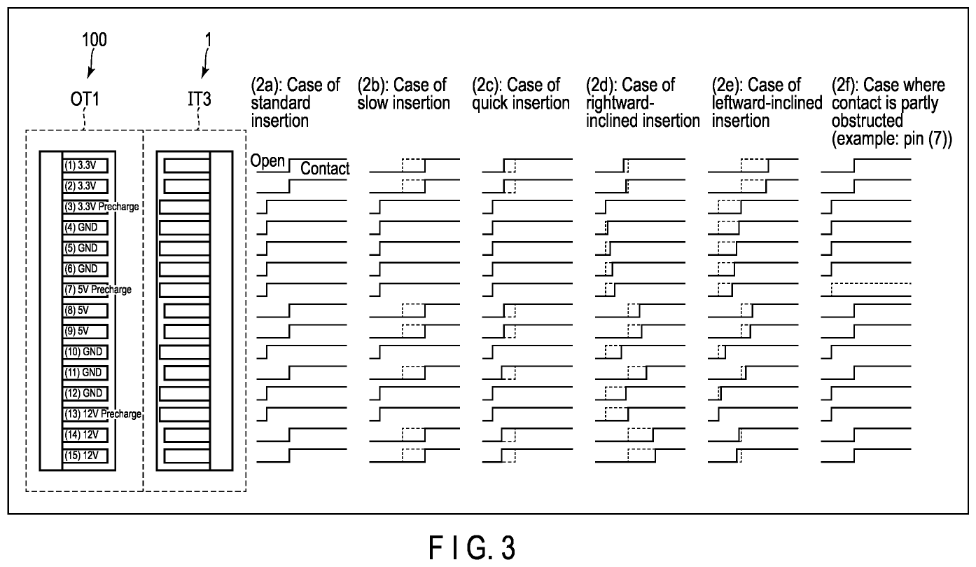

FIG. 3 is a schematic view showing an example of timing of manually connecting between output terminals OT1 of a SATA power source of the electronic device 100 incompatible with hot swap and input terminals IT3 of a SATA power source of the electronic device 1 incompatible with hot swap. In FIG. 3, the output terminals OT1 of the SATA power source of the electronic device 100 incompatible with hot swap and input terminals IT3 of the SATA power source of the electronic device 1 incompatible with hot swap are shown. In FIG. 3, the output terminals OT1 include fifteen pins. In FIG. 3, the lengths of the fifteen pins of the output terminals OT1 are equal to each other.

In FIG. 3, a pattern (2a) indicating the timing of contact (or connection) between each of the pins of the output terminals OT1 and each of the pins of the input terminals IT3 of a case where the output terminals OT1 incompatible with hot swap and input terminals IT3 incompatible with hot swap are engaged with each other in a standard manner is shown. In the pattern (2a) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a standard manner, each of the pins of the output terminals OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern.

In FIG. 3, a pattern (2b) indicating the timing of contact (or connection) between each of the pins of the output terminals OT1 and each of the pins of the input terminals IT3 of a case where the output terminals OT1 incompatible with hot swap and input terminals IT3 incompatible with hot swap are engaged with each other in a slow manner is shown. In the pattern (2b) indicating the timing of contact between each of the pins of the output terminals OT1 and each of the pins of the input terminals IT3 of a case where the output terminals OT1 and input terminals IT3 are engaged with each other in a slow manner, each of the pins of the output terminals OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern. In the pattern (2b) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a slow manner, the pattern of the dotted line indicates the pattern (2a) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a standard manner.

In FIG. 3, a pattern (2c) indicating the timing of contact (or connection) between each of the pins of the output terminals OT1 and each of the pins of the input terminals IT3 of a case where the output terminals OT1 incompatible with hot swap and input terminals IT3 incompatible with hot swap are engaged with each other in a quick manner is shown. In the pattern (2c) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a quick manner, each of the pins of the output terminals OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern. In the pattern (2c) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a quick manner, the pattern of the dotted line indicates the pattern (2a) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a standard manner.

In FIG. 3, a pattern (2d) indicating the timing of contact (or connection) between each of the pins of the output terminals OT1 and each of the pins of the input terminals IT3 of a case where the output terminals OT1 incompatible with hot swap and input terminals IT3 compatible with hot swap are engaged with each other in a rightward-inclined manner is shown. In the pattern (2d) indicating the timing of contact between each of the pins of the output terminals OT1 and each of the pins of the input terminals IT3 of a case where the output terminals OT1 and input terminals IT3 are engaged with each other in a rightward-inclined manner, each of the pins of the output terminals OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern. In the pattern (2d) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a rightward-inclined manner, the pattern of the dotted line indicates the pattern (2a) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a standard manner.

In FIG. 3, a pattern (2e) indicating the timing of contact (or connection) between each of the pins of the output terminals OT1 and each of the pins of the input terminals IT3 of a case where the output terminals OT1 incompatible with hot swap and input terminals IT3 incompatible with hot swap are engaged with each other in a leftward-inclined manner is shown. In the pattern (2e) indicating the timing of contact between each of the pins of the output terminals OT1 and each of the pins of the input terminals IT3 of a case where the output terminals OT1 and input terminals IT3 are engaged with each other in a leftward-inclined manner, each of the pins of the output terminals OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern. In the pattern (2e) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a leftward-inclined manner, the pattern of the dotted line indicates the pattern (2a) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a standard manner.

In FIG. 3, a pattern (2f) indicating the timing of contact (or connection) between each of the pins of the output terminals OT1 and each of the pins of the input terminals IT3 of a case where the output terminals OT1 incompatible with hot swap and input terminals IT3 incompatible with hot swap are engaged with each other in a state where part of the contact (connection) is obstructed by contamination or the like with a foreign substance is shown. In the pattern (2f) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a state where part of the contact (connection) is obstructed, each of the pins of the output terminals OT1 and each of the pins of the input terminals IT3 come into contact with each other (are connected to each other) at such timing that the state of contact rises from the opened (disconnected, turned-off or off) state corresponding to the lower pattern to the contacted (connected or on) state corresponding to the higher pattern. In the pattern (2f) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a state where part of the contact (connection) is obstructed, the pattern of the dotted line indicates the pattern (2a) indicating the timing of contact between each of the pins of the output terminals OT1 and each of the pins of the input terminals IT3 of a case where the output terminals OT1 incompatible with hot swap and input terminals IT3 incompatible with hot swap are engaged with each other in a standard manner.

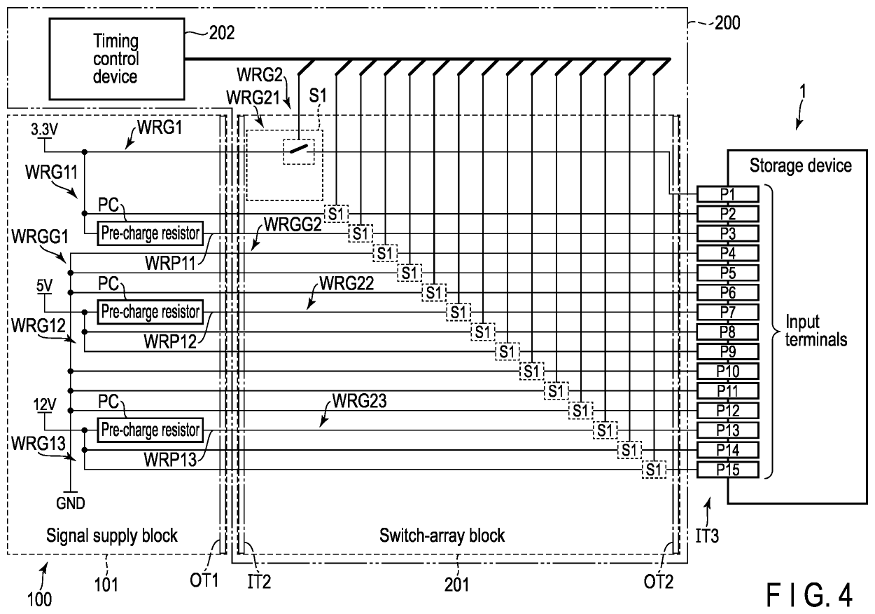

FIG. 4 is an outline view showing a configuration example of the connection tester 200 according to this embodiment.

The electronic device 100 includes a signal supply block 101 and output terminals OT1. The signal supply block 101 supplies a signal or power source. For example, the signal supply block 101 supplies power sources (voltages or currents). The signal supply block 101 includes a wiring group (or signal-line group) WRG1 including a plurality of wiring members (or signal lines) connected to GND and the power sources. In the example shown in FIG. 4, the wiring group WRG1 includes a wiring group WRG11 including a plurality of wiring members, for example, three wiring members connected to a 3.3 V power source, wiring group WRG12 including a plurality of wiring members, for example, three wiring members connected to a 5 V power source, wiring group WRG13 including a plurality of wiring members, for example, three wiring members connected to a 12 V power source, and wiring group WRGG1 including a plurality of wiring members, for example, six wiring members connected to GND. In the example shown in FIG. 4, one wiring member WRP11 belonging to the wiring group WRG11 includes a pre-charge resistor PC. One wiring member WRP12 belonging to the wiring group WRG12 includes a pre-charge resistor PC. One wiring member WRP13 belonging to the wiring group ERG13 includes a pre-charge resistor PC. The wiring groups WRG11, WRG12, WRG13, and WRGG1 are each electrically connected to the output terminals OT1.

The output terminals OT1 includes pins (hereinafter referred to as the output pins corresponding to the wiring group WRG11 in some cases) connected to the wiring members of the wiring group WRG11, pins (hereinafter referred to as the output pins corresponding to the wiring group WRG12 in some cases) connected to the wiring members of the wiring group WRG12, pins (hereinafter referred to as the output pins corresponding to the wiring group WRG13 in some cases) connected to the wiring members of the wiring group WRG13, and pins (hereinafter referred to as the output pins corresponding to the wiring group WRGG1 in some cases) connected to the wiring members of the wiring group WRGG1.

The electronic device 1 includes input terminals IT3. The input terminals IT3 include pins P1, P2, P3, P4, P5, P6, P7, P8, P9, P10, P11, P12, P13, P14, and P15.

The connection tester 200 includes a switch-array block 201, input terminals IT2, output terminals OT2, and timing control device 202. It should be noted that the timing control device 202 may also be provided as an independent device separate from the connection tester 200.

The switch-array block 201 includes a wiring group WRG2 including a plurality of wiring members, for example, fifteen wiring members, and switches (or switch group including a plurality of switches) S1. The wiring group WRG2 is electrically connected to the wiring group WRG1. The wiring group WRG2 includes a wiring group WRG21 electrically connected to the wiring group WRG11, wiring group WRG22 electrically connected to the wiring group WRG12, wiring group WRG23 electrically connected to the wiring group WRG13, and wiring group WRGG2 electrically connected to the wiring group WRGG1. Each of the switches S1 carries out break and make (opening and closing) to thereby switch between the on-state and off-state of a signal or electricity. The switch S1 includes, for example, a relay element. When in the break state or in the opened state, the switch S1 makes the signal, communication by electricity or supply of power in the off-state and, when in the make state or in the closed state, makes the signal, communication by electricity or supply of power in the on-state. In the example shown in FIG. 4, each of the switches S1 is provided in each of the wiring members of the wiring group WRG2, and switches between the on-state and off-state of the signal, communication by electricity or supply of power of each of the wiring members of the wiring group WRG2.

The input terminals IT2 are connected to the output terminals OT1. The input terminals IT2 includes pins (hereinafter referred to as the input pins corresponding to the wiring group WRG21 in some cases) connected to the wiring members of the wiring group WRG21, pins (hereinafter referred to as the input pins corresponding to the wiring group WRG22 in some cases) connected to the wiring members of the wiring group WRG22, pins (hereinafter referred to as the input pins corresponding to the wiring group WRG23 in some cases) connected to the wiring members of the wiring group WRG23, and pins (hereinafter referred to as the input pins corresponding to the wiring group WRGG2 in some cases) connected to the wiring members of the wiring group WRGG2. When the input terminals IT2 are connected to the output terminals OT1, the input pins corresponding to the wiring group WRG21 are electrically connected to the output pins corresponding to the wiring group WRG11. When the input terminals IT2 are connected to the output terminals OT1, the input pins corresponding to the wiring group WRG22 are electrically connected to the output pins corresponding to the wiring group WRG12. When the input terminals IT2 are connected to the output terminals OT1, the input pins corresponding to the wiring group WRG23 are electrically connected to the output pins corresponding to the wiring group WRG13. When the input terminals IT2 are connected to the output terminals OT1, the input pins corresponding to the wiring group WRGG2 are electrically connected to the output pins corresponding to the wiring group WRGG1.

The output terminals OT2 are connected to the input terminals IT3. The output terminals OT2 includes pins (hereinafter referred to as the output pins corresponding to the wiring group WRG21 in some cases) connected to the wiring members of the wiring group WRG21, pins (hereinafter referred to as the output pins corresponding to the wiring group WRG22 in some cases) connected to the wiring members of the wiring group WRG22, pins (hereinafter referred to as the output pins corresponding to the wiring group WRG23 in some cases) connected to the wiring members of the wiring group WRG23, and pins (hereinafter referred to as the output pins corresponding to the wiring group WRGG2 in some cases) connected to the wiring members of the wiring group WRGG2. When the output terminals OT2 are connected to the input terminals IT3, the output pins corresponding to the wiring group WRG21 are electrically connected to the pins P1, P2, and P3. When the output terminals OT2 are connected to the input terminals IT3, the output pins corresponding to the wiring group WRG22 are electrically connected to the pins P7, P8, and P9. When the output terminals OT2 are connected to the input terminals IT3, the output pins corresponding to the wiring group WRG23 are electrically connected to the pins P13, P14, and P15. When the output terminals OT2 are connected to the input terminals IT3, the output pins corresponding to the wiring group WRGG2 are electrically connected to the pins P4, P5, P6, P10, P11, and P12.

The timing control device 202 controls connection timing. The timing control device 202 reproduces the connection timing for manually connecting the input terminals IT3 of the electronic device 1 compatible with hot swap and output terminals OT1 of the electronic device 100 compatible with hot swap to each other. For example, the timing control device 202 reproduces the patterns of the contact (or connection) timing of (1a) to (1f) shown in FIG. 2. The timing control device 202 reproduces the connection timing for manually connecting the input terminals IT3 of the electronic device 1 incompatible with hot swap and output terminals OT1 of the electronic device 100 incompatible with hot swap to each other. For example, the timing control device 202 reproduces the patterns of the contact (or connection) timing of (2a) to (2f) shown in FIG. 3. It should be noted that the timing control device 202 may also be capable of reproducing the patterns of connection timing for connecting the input terminal IT3 of the electronic device 1 and output terminals OT1 of the electronic device 100 to each other excluding the patterns of the contact (or connection) timing of (1a) to (1f) shown in FIG. 2 and patterns of the contact (or connection) timing of (2a) to (2f) shown in FIG. 3. The timing control device 202 is, for example, a personal computer.

In the example shown in FIG. 4, the timing control device 202 is electrically connected to the plurality of switches S1 with wiring or the like, and controls break and make (opening and closing or on/off) of the plurality of switches S1. By controlling on/off of the plurality of switches S1, the timing control device 202 reproduces various patterns of connection timing for connecting the input terminals IT3 of the electronic device 1 and output terminals OT1 of the electronic device 100 to each other. For example, the timing control device 202 controls on/off of the plurality of switches S1 to thereby reproduce the connection timing for manually connecting the input terminals IT3 of the electronic device 1 compatible with hot swap and output terminals OT1 of the electronic device 100 compatible with hot swap to each other. In other words, the timing control device 202 controls on/off of the plurality of switches S1 to thereby artificially reproduce the state where the input terminals IT3 of the electronic device 1 and output terminals OT1 of the electronic device 100 are connected to each other by hot swap (hot plug) and reproduce the connection timing for manually connecting the input terminals IT3 of the electronic device 1 compatible with hot swap and output terminals OT1 of the electronic device 100 compatible with hot swap to each other. For example, the timing control device 202 controls on/off of the plurality of switches S1 to thereby reproduce the connection timing for manually connecting the input terminals IT3 of the electronic device 1 incompatible with hot swap and output terminals OT1 of the electronic device 100 incompatible with hot swap to each other. In other words, the timing control device 202 controls on/off of the plurality of switches S1 to thereby artificially reproduce the state where the input terminals IT3 of the electronic device 1 and output terminals OT1 of the electronic device 100 are connected to each other by hot swap (hot plug) and reproduce the connection timing for manually connecting the input terminals IT3 of the electronic device 1 incompatible with hot swap and output terminals OT1 of the electronic device 100 incompatible with hot swap to each other. Hereinafter, the expression “artificially reproducing the state where connection is carried out by hot swap (hot plug)” is called “artificial hot swap” or “artificial hot plug” in some cases.

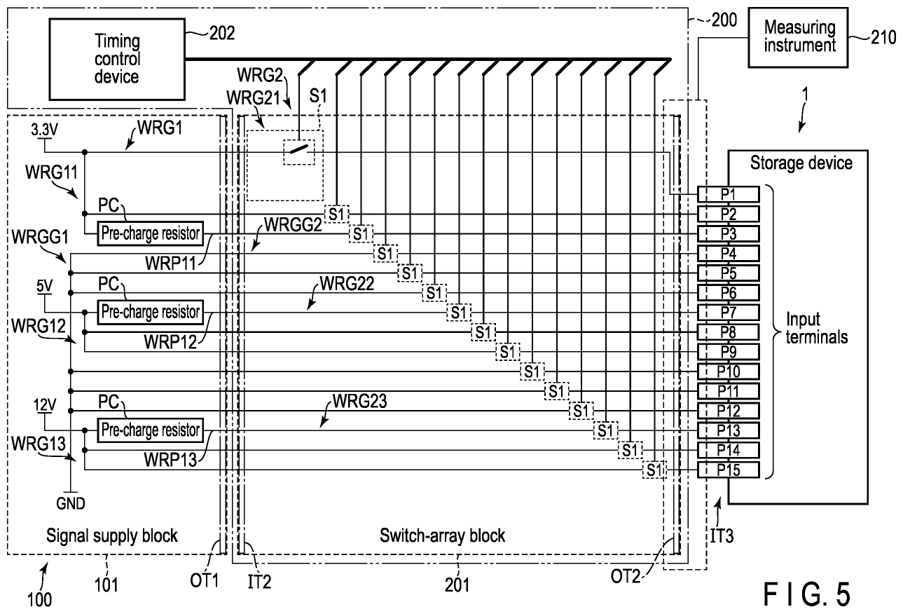

FIG. 5 is an outline view showing an example of a method of measuring currents and voltages of the connection tester 200 and electronic device 1. FIG. 5 corresponds to FIG. 4.

A measuring instrument 210 is configured to measure (or monitor) currents and voltages. In the example shown in FIG. 5, the measuring instrument 210 measures currents and voltages of the connection tester 200 and electronic device 1. For example, the measuring instrument 210 measures currents and voltages of the pins of the output terminals OT2 of the connection tester 200 and pins of the input terminals IT3 of the electronic device 1. The measuring instrument 210 stores measurement results of the currents and voltages of the pins of the output terminals OT2 of the connection tester 200 and pins of the input terminals IT3 of the electronic device 1, and patterns of timing of connection between the pins of the output terminals OT2 of the connection tester 200 and pins of the input terminals IT3 of the electronic device 1 in a particular system or particular recording device in correlation with each other. It should be noted that the connection tester 200 may also include the measuring instrument 210. Further, the measuring instrument 210 may not be provided.

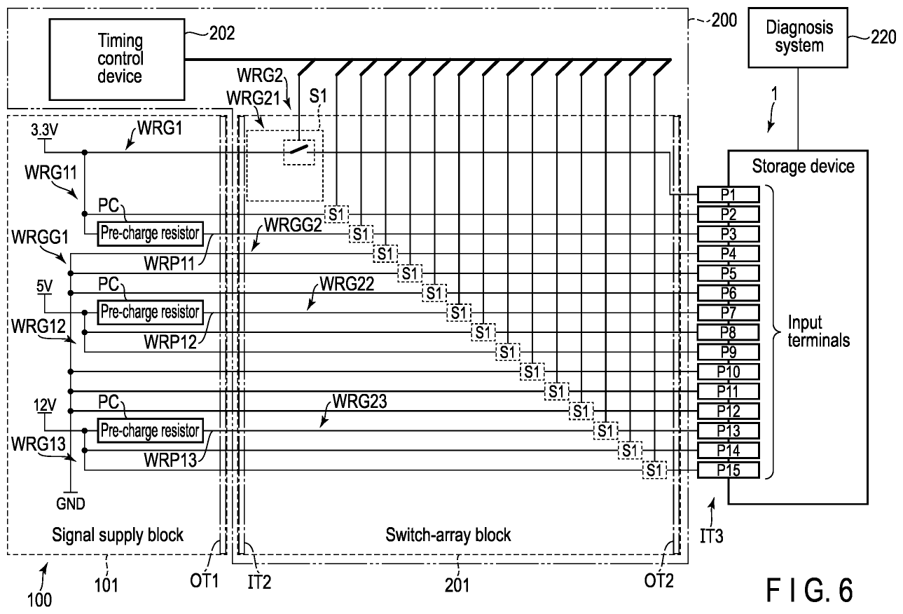

FIG. 6 is an outline view showing an example of a method of confirming the state of the electronic device 1 of a case where the electronic device 100 is electrically connected thereto by artificial hot plug by the connection tester 200. FIG. 6 corresponds to FIG. 4.

A diagnosis system 220 diagnoses the state of the electronic device 1. In the example shown in FIG. 6, the diagnosis system 220 is connected to the electronic device 1 with wiring different from the connection tester 200. The diagnosis system 220 diagnoses the state of the electronic device 1 of a case where the electronic device 100 is electrically connected thereto by artificial hot plug by the connection tester 200. In other words, the diagnosis system 220 diagnoses whether or not the electronic device 1 of the case where the electronic device 100 is electrically connected thereto by hot plug by the connection tester 200 normally operates. The diagnosis system 220 stores the diagnosis of the state of the electronic device 1 of a case where the electronic device 100 is electrically connected thereto by artificial hot plug by the connection tester 200, and patterns of the connection timing for connection between the pins of the output terminals OT2 of the connection tester 200 and pins of the input terminals IT3 of the electronic device 1 in a particular system or particular recording device in correlation with each other. It should be noted that when a signal is input from the output terminals OT2 of the connection tester 200 to the input terminals IT3 of the electronic device 1, the interface of the diagnosis system 220 needs to double as the contrivance for supplying the signal. Further, the connection tester 200 may include the diagnosis system 220.

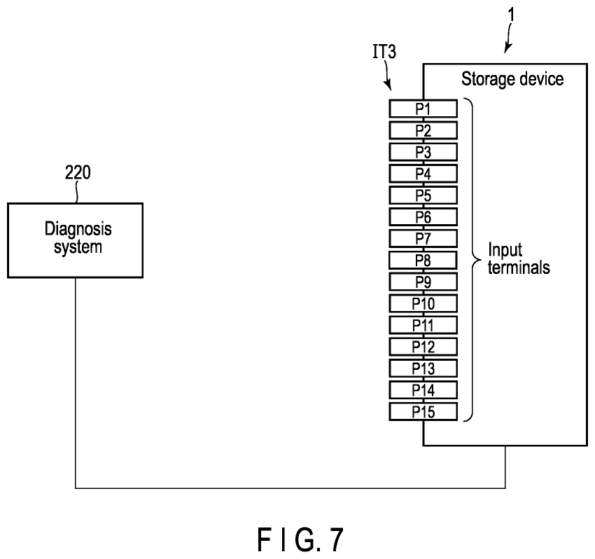

FIG. 7 is an outline view showing an example of a method of confirming the state of the electronic device 1 of a case where the electronic device 100 is electrically connected thereto by artificial hot plug by the connection tester 200.

In the example shown in FIG. 7, the diagnosis system 220 diagnoses the state of the electronic device 1 after being subjected by the connection tester 200 to a test of electrical connection to the electronic device 100 by artificial hot plug.

According to this embodiment, the connection tester 200 includes a switch-array block 201, input terminals IT2, output terminals OT2, and timing control device 202. The pins of the output terminals OT1 of the electronic device 100 are connected to the pins of the input terminals IT2 of the connection tester 200. The pins of the input terminals IT3 of the electronic device 1 are connected to the pins of the output terminals OT2 of the connection tester 200. The switch-array block 201 includes the wiring group WRG2 connecting the pins of the input terminals IT2 and pins of the output terminals OT2 to each other, and switch S1 provided in each of the wiring members of the wiring group WRG2. The timing control device 202 is connected to the switches S1 with the wiring members and the like, and controls on/off of the switches S1. The timing control device 202 controls on/off of the switches S1 to thereby electrically connect the input terminals IT3 of the electronic device 1 to the output terminals OT1 of the electronic device 100 by artificial hot plug, and reproduce the connection timing for manually connecting the input terminals IT3 of the electronic device 1 and output terminals OT1 of the electronic device 100 to each other. The connection tester 200 can carry out a test of automatically connecting the output terminals OT1 of the electronic device 100 and input terminals IT3 of the electronic device 1 to each other by hot swap. Further, the connection tester 200 can reproduce various patters of timing for connection between the input terminals IT3 of the electronic device 1 and output terminals OT1 of the electronic device 100. Further, the connection tester 200 has a configuration including only low-priced components and no movable part. Accordingly, the connection tester 200 can easily carry out the connection test of the terminals.

Next, a connection tester according to each of an embodiment and modified examples other than the first embodiment described previously will be described below. In another embodiment and in other modified examples, parts identical to the above-described first embodiment are denoted by reference symbols identical to the first embodiment and detailed descriptions of the parts are omitted.

### MODIFIED EXAMPLE 1

A connection tester 200 of a modified example 1 differs from the connection tester 200 of the first embodiment described previously in the configuration of the switch-array block 201.

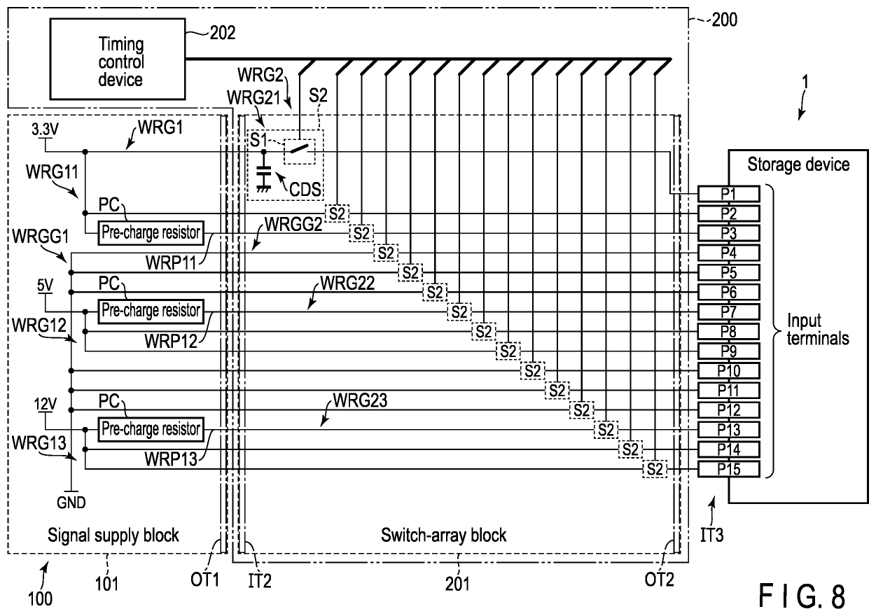

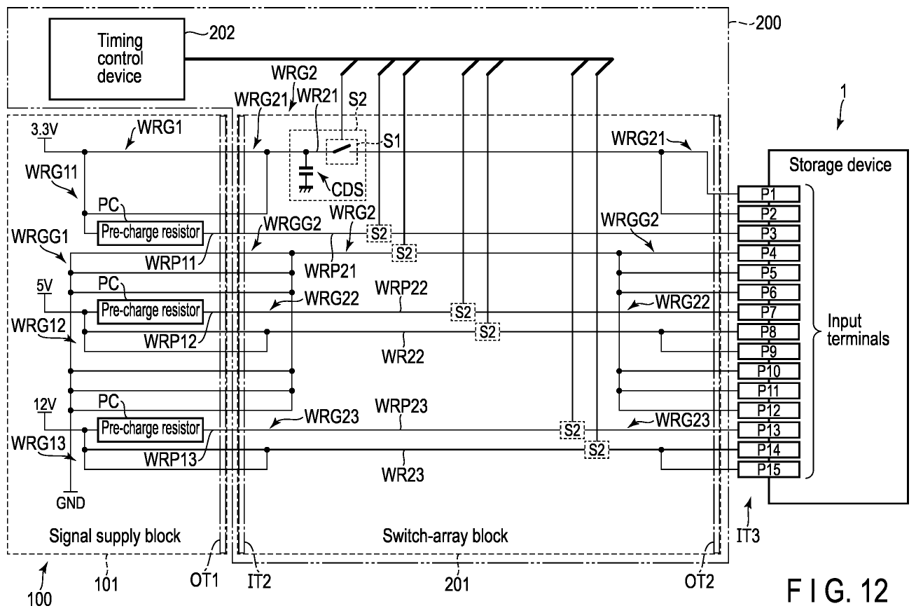

FIG. 8 is an outline view showing a configuration example of the connection tester 200 according to the modified example 1. The switch-array block 201 shown in FIG. 8 corresponds to a configuration obtained by replacing the switch S1 of the switch-array block 201 shown in FIG. 12 with a switch S2.

The switch-array block 201 includes switches (or switch group) S2. The switch S2 includes a switch S1 and capacitor (compensating capacitor) CDS. The capacitor CDS is provided at part of the wiring member connected to the switch S1 immediately before the switch S1. In other words, the capacitor CDS is provided on the wiring member (each wiring member of the wiring group WRG2) between the input terminal IT2 and switch S1. That is, the capacitor CDS is provided on the wiring member (a part of each of wiring members of the wiring group WRG2) connecting between the input terminal IT2 and switch S1. In other words, the capacitor CDS is provided on a part of the wiring (a part of each of wiring members of the wiring group WRG2) on the input terminal IT2 side of the switch S1. In the example shown in FIG. 8, the switch S2 is provided in each of the wiring members of the wiring group WRG2, and switches between the on-state and off-state of the signal, communication by electricity or supply of power of each of the wiring members of the wiring group WRG2.

According to the modified example 1, the connection tester 200 includes the switch-array block 201 including the switches S2 provided in the wiring members of the wiring group WRG2. The switch S2 includes the switch S1 and capacitor CDS provided at a part of the wiring member connected to the switch S1 immediately before the switch S1. The connection tester 200 can compensate for the adverse influence of the rush current of the case where the output terminals OT1 of the electronic device 100 and input terminals IT3 of the electronic device 1 are electrically connected to each other by artificial hot plug. Further, the connection tester 200 can prevent the adverse influence of the wiring impedance of the case where the output terminals OT1 of the electronic device 100 and input terminals IT3 of the electronic device 1 are electrically connected to each other by artificial hot plug from occurring.

### MODIFIED EXAMPLE 2

A connection tester 200 of a modified example 2 differs from the connection tester 200 of each of the first embodiment and modified example 1 described previously in the configuration of the switch-array block 201.

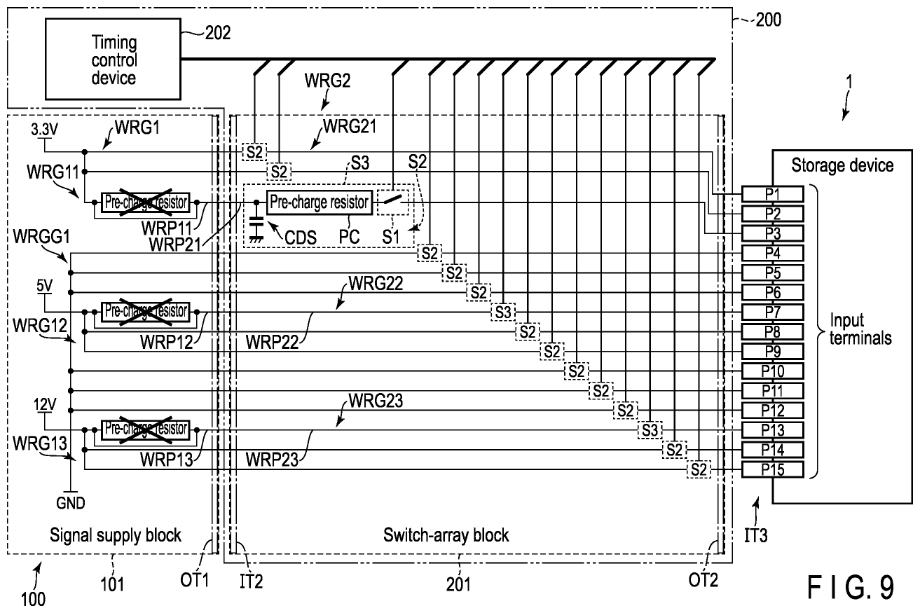

FIG. 9 is an outline view showing a configuration example of a connection tester according to the modified example 2. The switch-array block 201 shown in FIG. 9 corresponds to a configuration obtained by replacing a part of the switches S2 of the switch-array block 201 shown in FIG. 8 with switches S3.

In the example shown in FIG. 9, as to the one wiring member WRP11 belonging to the wiring group WRG11, a pre-charge resistor PC is not included therein or is removed from the wiring member WRP11. As to the one wiring member WRP12 belonging to the wiring group WRG12, a pre-charge resistor PC is not included therein or is removed from the wiring member WRP12. As to the one wiring member WRP13 belonging to the wiring group WRG13, a pre-charge resistor PC is not included therein or is removed from the wiring member WRP13.

The switch-array block 201 includes the wiring group WRG2, switches S2, and switches (or switch group) S3. The wiring group WRG21 of the wiring group WRG2 includes the wiring member WRP21 electrically connected to the wiring member WRP11. The wiring group WRG22 of the wiring group WRG2 includes the wiring member WRP22 electrically connected to the wiring member WRP12. The wiring group WRG23 of the wiring group WRG2 includes the wiring member WRP23 electrically connected to the wiring member WRP13. The switch S2 is provided in each of the wiring members of the wiring group WRG2 other than the wiring members WRP21, WRP22, and WRP23, and switches between the on-state and off-state of the signal, communication by electricity or supply of power of each of the wiring members of the wiring group WRG2 other than the wiring members WRP21, WRP22, and WRP23. The switch S3 includes a switch S2 and pre-charge resistor PC. The pre-charge resistor PC is provided in a part of the wiring member connecting between the capacitor CDS and switch S1 immediately before the switch S1. In the example shown in FIG. 9, the switch S3 is provided in each of the wiring members WRP21, WRP22, and WRP23, and switches between the on-state and off-state of the signal, communication by electricity or supply of power of each of the wiring members WRP21, WRP22, and WRP23.

According to the modified example 2, the connection tester 200 includes the switch-array block 201 including the switches S3 provided in the wiring members WRP21, WRP22, and WRP23. In the connection tester 200, it is possible to compensate for the loss of the effect of the pre-charge resistor PC for reducing the rush current of the electronic device 1 attributable to the arrangement of the capacitor CDS with the switch S3.

### MODIFIED EXAMPLE 3

A connection tester 200 of a modified example 3 differs from the connection tester 200 of each of the first embodiment, modified example 1, and modified example 2 described previously in the configuration.

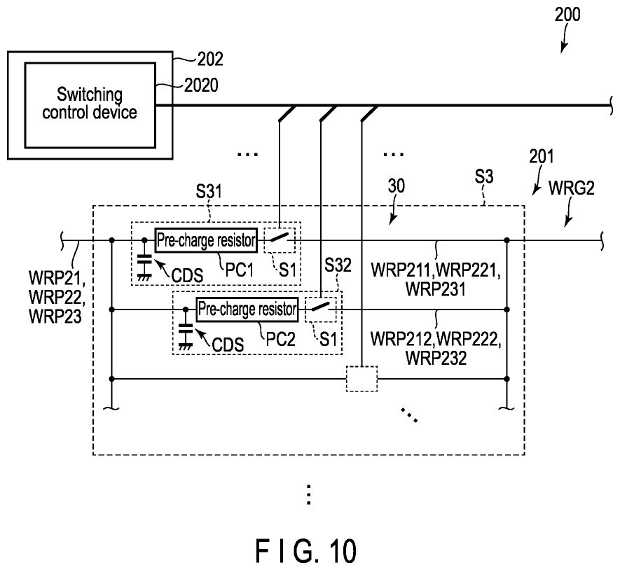

FIG. 10 is an outline view showing a configuration example of the connection tester 200 according to the modified example 3. FIG. 10 corresponds to FIG. 9.

The switch S3 includes a plurality of switches S30. The plurality of switches S30 include pre-charge resistors having resistance values different from each other. The plurality of switches S30 include, for example, switches S31, S32, and so on. Further, the plurality of switches S30 may include three or more switches S30. The switch S31 includes a switch S1, capacitor CDS provided at a part of the wiring member connected to the switch S1 immediately before the switch S1, and pre-charge resistor PC1 provided in a part of the wiring member connecting between the switch S1 and capacitor CDS immediately before the switch S1. The switch S32 includes a switch S1, capacitor CDS provided at a part of the wiring member immediately before the switch S1, and pre-charge resistor PC2 having a resistance value different from the resistance value of the pre-charge resistor PC1 and provided in a part of the wiring member connecting between the switch S1 and capacitor CDS immediately before the switch S1. In the example shown in FIG. 10, the switches S31 and S32 are connected in parallel with each other with the wiring members WRP211 and WRP212 both branched from the wiring member WRP21, and switch between the on-state and off-state of the signal, communication by electricity or supply of power of the wiring member WRP21. The switches S31 and S32 are connected in parallel with each other with the wiring members WRP221 and WRP222 both branched from the wiring member WRP22, and switch between the on-state and off-state of the signal, communication by electricity or supply of power of the wiring member WRP22. The switches S31 and S32 are connected in parallel with each other with the wiring members WRP231 and WRP232 both branched from the wiring member WRP23, and switch between the on-state and off-state of the signal, communication by electricity or supply of power of the wiring member WRP23. The switch S31 is provided in each of the wiring members WRP211, WRP221, and WRP231. In the switch S31, the switch S1 is provided in each of the wiring members WRP211, WRP221, and WRP231. In the switch S31, the capacitor CDS is provided at a part of each of the wiring members WRP211, WRP221, and WRP231 each connecting between the input terminal IT2 and switch S1. In other words, in the switch S31, the capacitor CDS is provided at a part of each of the wiring members WRP211, WRP221, and WRP231 on the input terminal IT2 side of the switch S1. In the switch S31, the pre-charge resistor PC1 is provided in a part of each of the wiring members WRP211, WRP221, and WRP231 each connecting between the capacitor CDS and switch S1. In other words, in the switch S31, the pre-charge resistor PC1 is provided in a part of each of the wiring members WRP211, WRP221, and WRP231 on the switch S1 side of the capacitor CDS and on the input terminal IT2 side of the switch S1. The switch S32 is provided in each of the wiring members WRP212, WRP222, and WRP232. In the switch S32, the switch S1 is provided in each of the wiring members WRP212, WRP222, and WRP232. In the switch S32, the capacitor CDS is provided at a part of each of the wiring members WRP212, WRP222, and WRP232 each connecting between the input terminal IT2 and switch S1. In other words, in the switch S32, the capacitor CDS is provided at a part of each of the wiring members WRP212, WRP222, and WRP232 on the input terminal IT2 side of the switch S1. In the switch S32, the pre-charge resistor PC2 is provided in a part of each of the wiring members WRP212, WRP222, and WRP232 each connecting between the capacitor CDS and switch S1. In other words, in the switch S32, the pre-charge resistor PC2 is provided in a part of each of the wiring members WRP212, WRP222, and WRP232 on the switch S1 side of the capacitor CDS and on the input terminal IT2 side of the switch S1. It should be noted that the switch S3 may include a variable resistor.

The timing control device 202 includes a switching control device 2020. The switching control device 2020 is electrically connected to a plurality of switches 30, and switches between the on-state and off-state of each of the plurality of switches 30. For example, the switching control device 2020 is electrically connected to the switches S31 and S32. When the switching control device 2020 turns on, for example, the switch S31, turns off the switch S32 and, when the switching control device 2020 turns on the switch S32, turns off the switch S31.

According to the modified example 3, the connection tester 200 includes the switch-array block 201 including the switches S3 each including the plurality of switches 30 including the pre-charge resistors having the resistance values different from each other, and timing control device 202 including the switching control device 2020 for switching between the on-state and off-state of each of the plurality of switches 30. Accordingly, the connection tester 200 can easily carry out the connection test of terminals of pre-charge resistors having various resistance values.

### MODIFIED EXAMPLE 4

A connection tester 200 of a modified example 4 differs from the connection tester 200 of each of the first embodiment, modified example 1, modified example 2, and modified example 3 described previously in the configuration of the switch-array block 201.

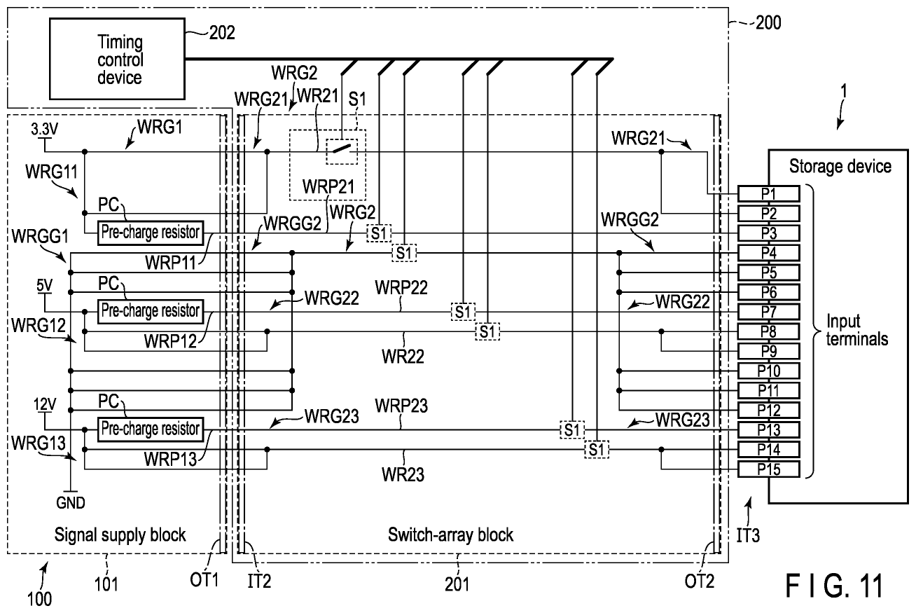

FIG. 11 is an outline view showing a configuration example of the connection tester 200 according to the modified example 4. The switch-array block 201 shown in FIG. 11 corresponds to a configuration obtained by putting together the wiring members of the same family in the switch-array block 201 shown in FIG. 4 into one wiring member.

The switch-array block 201 includes a wiring group WRG2 and switches S1. In the wiring group WRG21, wiring members of the same family, for example, wiring members other than the wiring member WRP21 are connected to the wiring member WR21. In the wiring group WRG22, wiring members of the same family, for example, wiring members other than the wiring member WRP22 are connected to the wiring member WR22. In the wiring group WRG23, wiring members of the same family, for example, wiring members other than the wiring member WRP23 are connected to the wiring member WR23. Each of the wiring members WR21, WR22, and WR23 has sufficient electrical capacitance, and has electrical capacitance greater than the electrical capacitance of each of the wiring members of the wiring group WRG21, wiring members of the wiring group WRG22, and wiring members of the wiring group WRG23. In the example shown in FIG. 11, the switch S1 is provided in each of the wiring members WR21, WR22, WR23, WRP21, WRP22, and WRP23, and switches between the on-state and off-state of the signal, communication by electricity or supply of power of each of the wiring members WR21, WR22, WR23, WRP21, WRP22, and WRP2.

According to the modified example 4, the connection tester 200 includes the switch-array block 201 including the switch S1 provided in each of the wiring members each of which is formed by putting together wiring members of the same family into one wiring member. Accordingly, it is possible to simplify the configuration of the connection tester 200.

### MODIFIED EXAMPLE 5

A connection tester 200 of a modified example 5 differs from the connection tester 200 of each of the first embodiment, and modified examples 1 to 4 described previously in the configuration of the switch-array block 201.

FIG. 12 is an outline view showing a configuration example of the connection tester 200 according to the modified example 5. The switch-array block 201 shown in FIG. 12 corresponds to a configuration obtained by replacing the switches S1 of the switch-array block 201 shown in FIG. 11 with switches S2.

In the example shown in FIG. 12, the switch S2 is provided in each of the wiring members WR21, WR22, WR23, WRP21, WRP22, and WRP23, and switches between the on-state and off-state of the signal, communication by electricity or supply of power of each of the wiring members WR21, WR22, WR23, WRP21, WRP22, and WRP23.

According to the modified example 5, the connection tester 200 can compensate for the adverse influence of the rush current of the case where the output terminals OT1 of the electronic device 100 and input terminals IT3 of the electronic device 1 are electrically connected to each other by artificial hot plug. Further, the connection tester 200 can prevent the adverse influence of the wiring impedance of the case where the output terminals OT1 of the electronic device 100 and input terminals IT3 of the electronic device 1 are electrically connected to each other by artificial hot plug from occurring.

### MODIFIED EXAMPLE 6

A connection tester 200 of a modified example 6 differs from the connection tester 200 of each of the first embodiment, and modified examples 1 to 5 described previously in the configuration of the switch-array block 201.

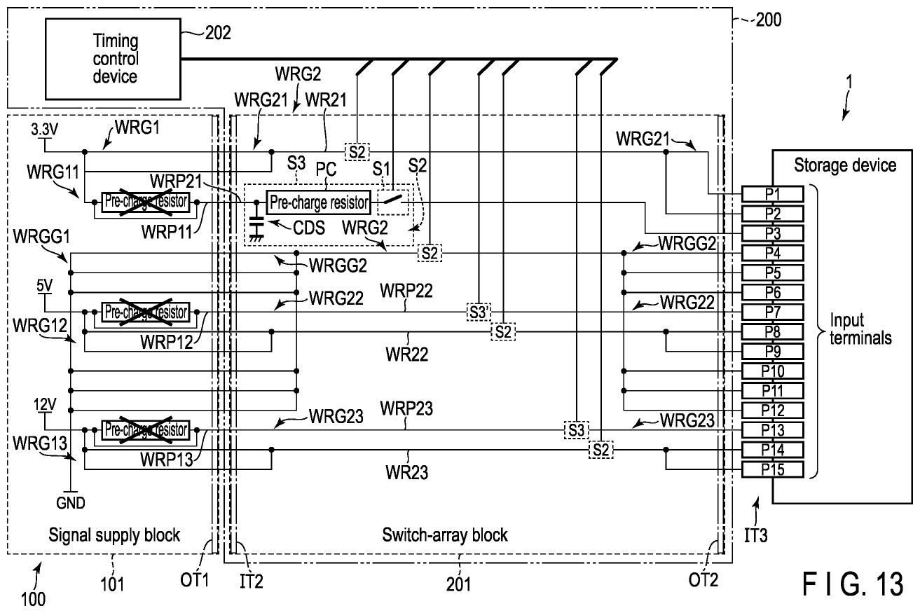

FIG. 13 is an outline view showing a configuration example of the connection tester 200 according to the modified example 6. The switch-array block 201 shown in FIG. 13 corresponds to a configuration obtained by replacing a part of the switches S2 of the switch-array block 201 shown in FIG. 12 with switches S3.

In the example shown in FIG. 13, as to the one wiring member WRP11 belonging to the wiring group WRG11, a pre-charge resistor PC is not included therein or is removed from the wiring member WRP11. As to the one wiring member WRP12 belonging to the wiring group WRG12, a pre-charge resistor PC is not included therein or is removed from the wiring member WRP12. As to the one wiring member WRP13 belonging to the wiring group WRG13, a pre-charge resistor PC is not included therein or is removed from the wiring member WRP13.

In the example shown in FIG. 13, the switch S3 is provided in each of the wiring members WRP21, WRP22, and WRP23, and switches between the on-state and off-state of the signal, communication by electricity or supply of power of each of the wiring members WRP21, WRP22, and WRP23.

According to the modified example 6, in the connection tester 200, it is possible to compensate for the loss of the effect of the pre-charge resistor PC for reducing the rush current of the electronic device 1 attributable to the arrangement of the capacitor CDS with the switch S3.

### Second Embodiment

A connection tester 200 of a second embodiment differs from the connection tester 200 of each of the first embodiment, and modified examples 1 to 6 described previously in the configuration.

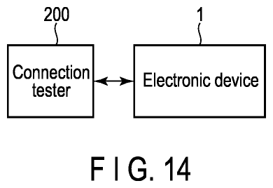

FIG. 14 is a block diagram showing an example of the connection tester 200 according to the second embodiment. In the example shown in FIG. 14, the electronic device 1 is connected to one end part of the connection tester 200.

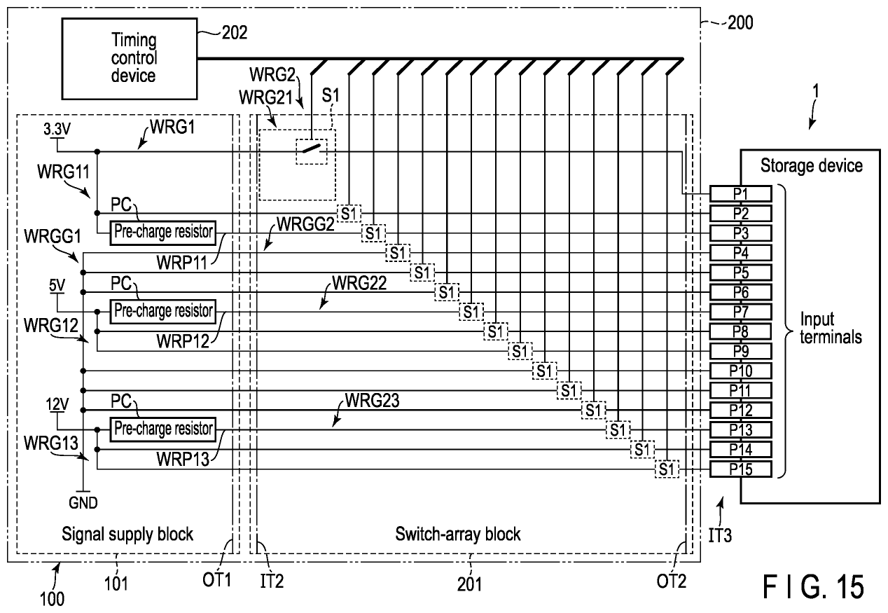

FIG. 15 is an outline view showing a configuration example of the connection tester 200 according to the second embodiment.

The connection tester 200 supplies a signal or power to the electronic device and controls electrical connection timing of the electronic device. The switch-array block 201 further includes a signal supply block 101 and output terminals OT1.

According to the second embodiment, the connection tester 200 includes the switch-array block 201 further including the signal supply block 101 and output terminals OT1. Accordingly, it is possible for the connection tester 200 to easily carry out the connection test of the terminals.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A connection tester comprising:
first input terminals connected to first output terminals of a signal supply unit which supplies a signal;
second output terminals connected to second input terminals of a device connectable to the first output terminals;
a plurality of wiring members connecting the first input terminals and the second output terminals to each other;
a plurality of switches respectively provided in the plurality of wiring members; and
a control unit which controls on/off timing of each of the plurality of switches.

2. The connection tester of claim 1, wherein
the first input terminals include a second wiring member electrically connected to a first wiring member belonging to the plurality of wiring members, and
the second wiring member includes a first resistor.

3. The connection tester of claim 1, further comprising
a first capacitor provided at a part of the first wiring member connecting between the first input terminal and a first switch belonging to the plurality of switches and provided in the first wiring member belonging to the plurality of wiring members.

4. The connection tester of claim 3, wherein
the first input terminals include the second wiring member electrically connected to the first wiring member, and
the second wiring member includes the first resistor.

5. The connection tester of claim 3, further comprising
the first resistor provided in a part of the first wiring member connecting between the first switch and the first capacitor.

6. The connection tester of claim 5, further comprising:
a second capacitor provided at a part of the second wiring member connecting between a second switch belonging the plurality of switches and provided in the second wiring member branched from the first wiring member and the first input terminal; and
a second resistor possessing a second resistance value different from a first resistance value of the first resistor and provided in a part of the second wiring member connecting between the second switch and the second capacitor, wherein
the control unit switches the first switch and the second switch.

7. The connection tester of claim 1, further comprising:
a third wiring member connected to the first wiring member belonging to the plurality of wiring members and the second wiring member; and
a first switch belonging to the plurality of switches and provided in the third wiring member.

8. The connection tester of claim 7, further comprising
a first capacitor provided at the third wiring member between the first input terminal and the first switch.

9. The connection tester of claim 8, further comprising
the first resistor provided in the third wiring member between the first capacitor and the first switch.

10. The connection tester of claim 1, wherein
the signal supply unit and the device are physically hot-swappable.

11. The connection tester of claim 10, wherein
the plurality of wiring members are divided into a plurality of wiring groups to which voltages different from each other are applied.

12. A connection tester comprising:
a signal supply unit which supplies a signal and includes first output terminals;
first input terminals connected to the first output terminals;
second output terminals connected to second input terminals of a device;
a plurality of wiring members connecting between the first input terminals and the second output terminals;
a plurality of switches each of which is provided in each of the plurality of wiring members; and
a control unit which controls on/off timing of each of the plurality of switches.

13. The connection tester of claim 12, wherein
the first input terminals include a second wiring member electrically connected to a first wiring member belonging to the plurality of wiring members, and
the second wiring member includes a first resistor.

14. The connection tester of claim 12, further comprising
a first capacitor provided at a part of the first wiring member connecting between the first input terminal and a first switch belonging the plurality of switches and provided in the first wiring member belonging to the plurality of wiring members.

15. The connection tester of claim 14, wherein
the first input terminals include the second wiring member electrically connected to the first wiring member, and
the second wiring member includes the first resistor.

16. The connection tester of claim 14, further comprising
the first resistor provided in a part of the first wiring member connecting between the first switch and the first capacitor.

17. The connection tester of claim 16, further comprising:
a second capacitor provided at a part of the second wiring member connecting between a second switch belonging the plurality of switches and provided in the second wiring member branched from the first wiring member and the first input terminal; and
a second resistor possessing a second resistance value different from a first resistance value of the first resistor and provided in a part of the second wiring member connecting between the second switch and the second capacitor, wherein
the control unit switches the first switch and the second switch.

18. The connection tester of claim 12, further comprising:
a third wiring member connected to the first wiring member belonging to the plurality of wiring members and the second wiring member; and
a first switch belonging to the plurality of switches and provided in the third wiring member.

19. The connection tester of claim 18, further comprising
a first capacitor provided at the third wiring member between the first input terminal and the first switch.

20. The connection tester of claim 19, further comprising
a first resistor provided in the third wiring member between the first capacitor and the first switch.
